(19) United States
(12) Patent Application Publication
(10) Pub. No.: US 2002/0089836 A1
(43) Pub. Date: Jul. 11, 2002

(54) INJECTION MOLDED UNDERFILL PACKAGE AND METHOD OF ASSEMBLY

(76) Inventors: KENZO ISHIDA, TSUKUBA (JP); KENJI TAKAHASHI, TSUKUBA (JP); JIRO KUBOTA, TSUKUBA (JP)

Correspondence Address: SCHWEGMAN LUNDBERG WOESSNER KLUTH P A, P O BOX 2938, MINNEAPOLIS, MN, 55402

(21) Appl. No.: 09/427,230

(22) Filed: Oct. 26, 1999

(51) Int. Cl. H05K 5/06

(52) U.S. Cl. 361/824

(57) ABSTRACT

The present invention provides a method of attaching an integrated circuit die to a substrate. The method includes applying solder bumps to contact areas, and placing the inverted integrated circuit die in a desired location such that the solder bumps are in contact with contact areas of the integrated circuit die and the substrate. The solder bumps are heated to mount the die, such that the bumps form a connection between the substrate and the integrated circuit. The gap between the die and the substrate is underfilled by injecting a molding compound into a molding die positioned over the mounted integrated circuit die.

### FIELD OF THE INVENTION

The invention relates generally to mounting and packaging semiconductors, and more specifically to mounting flip-chip semiconductors to a substrate.

### BACKGROUND OF THE INVENTION

As the size of consumer devices employing semiconductors continues to shrink and the cost of such devices continues to fall, device manufacturers seek methods to incorporate semiconductors into their designs as efficiently as possible. The semiconductor should not require a large amount of space to mount, but must be securely and reliably affixed to the substrate. The mounting method employed also should be as simple as possible, minimizing the time and equipment needed to mount a semiconductor to a substrate.

Relatively large dice requiring hundreds of electrical connections are today routinely provided to device manufacturers in the form of Pin-Grid Arrays (PGAs), which encapsulate a die in a ceramic package and provide a large number of electronically connective pins arranged in an array extending from one surface of the package. A number of Small-Outline Integrated Circuit (SOIC) and flat-pack packages also are currently employed, which provide electrical connection to the encapsulated die via a number of electrical contacts or pins mounted on the edges of the package. But, all of these technologies require a method of mounting a large, complex die in a package.

Mounting the die to a substrate within the package becomes difficult in applications where hundreds of electrical connections are necessary. Traditional techniques that essentially comprised spot welding thin wires between die contact areas and pins external to the die package are not practical with the very large number and small physical size of connections in current dice and packages. More practical methods of mounting dice to substrates have been developed, and are also commonly applied to mounting dice directly to a circuit board.

One such technology is the flip-chip, which is an inverted die mounted in a bumping process. A flip chip is simply a die that is flipped over so the side of the die containing circuitry is nearest the mounting substrate. The flipped die is then physically and electrically mounted to the substrate.

The electrical connection of a flip chip to conductors attached to the substrate is done via the bumping process, which comprises flowing solder bumps between the contact areas of the die and the substrate. The solder bumps are typically applied to integrated circuit die contact areas, and the die is inverted and positioned before heating and flowing of the solder bumps. As the bumps are heated and are able to flow, the die essentially undergoes a fine self-alignment due to the surface tension forces of the flowing solder bump. The flowed solder bumps create a mechanical and electrical connection between the contact areas of the die and the contact areas of the substrate, but the mechanical connection is relatively weak. Also, the die surface remains exposed, suspended off the surface of the mounting substrate by the flowed solder bumps.

To seal the exposed die and create a better mechanical attachment between the die and the substrate, a liquid underfill is usually flowed under the bump-mounted die. The underfill flows by capillary action between the die and the substrate, and therefore takes considerable time and application from multiple points to ensure that unfilled voids do not remain between the die and the substrate. To ensure good bonding of the underfill material, flux used in bumping or flowing must be chemically removed, and the underfill material must flow easily between the die and the substrate. Underfill material is typically an epoxy-based fill that is suitably viscous to flow properly yet is mechanically strong after setting. The underfill is heated to drive out underfill solvents, and finally a molding material is applied over the mounted and underflowed die to completely seal the die.

Such a process enables relatively easy and efficient mounting of a die to a substrate, whether the substrate is a ceramic substrate of a PGA package, a printed circuit board, or another substrate onto which it is desirable to mount a die. But, the current flip-chip process is not as efficient as is desirable. The number of steps required to mount a chip and the time involved in the mounting process are still large enough that more efficient methods are sought. Reduction in equipment, in the number of steps needed to mount a flip chip, and in the time needed to mount a flip chip are all desired, and are addressed by this invention.

### SUMMARY OF THE INVENTION

The present invention provides a method of attaching an integrated circuit die to a substrate. The method includes applying solder bumps to contact areas, and placing the inverted integrated circuit die in a desired location such that the solder bumps are in contact with contact areas of the integrated circuit die and the substrate. The solder bumps are heated to mount the die, such that the bumps form a connection between the substrate and the integrated circuit. The gap between the die and the substrate is underfilled by injecting a molding compound into a molding die positioned over the mounted integrated circuit die.

### BRIEF DESCRIPTION OF THE FIGURES

FIG. 1 shows a flip chip mounted to a substrate.

FIG. 2 shows a flip chip mounted to a substrate, consistent with an embodiment of the present invention.

FIG. 3 shows a die and substrate wherein a contact surface comprises a nonoxidizing metal, consistent with an embodiment of the present invention

FIG. 4 shows an apparatus for application of molded underfill, consistent with an embodiment of the present invention.

FIG. 5 shows a side view of an apparatus for application of molded underfill, consistent with an embodiment of the present invention.

### DETAILED DESCRIPTION

In the following detailed description of sample embodiments of the invention, reference is made to the accompanying drawings which form a part hereof, and in which is shown by way of illustration specific sample embodiments in which the invention may be practiced. These embodiments are described in sufficient detail to enable those skilled in the art to practice the invention, and it is to be understood that other embodiments may be utilized and that logical, mechanical, electrical, and other changes may be made without departing from the spirit or scope of the present invention. The following detailed description is, therefore, not to be taken in a limiting sense, and the scope of the invention is defined only by the appended claims.

A less complex and time-consuming method of mounting a flip-chip to a substrate is desired, both to reduce manufacturing time and to reduce material and equipment costs associated with current processes. A mounting method providing superior adhesion and reliability is also desired, as is a method that allows application of superior thermal solutions to a mounted integrated circuit.

The present invention addresses these and other problems by providing a rapid and reliable method of mounting flip-chips on a substrate. The invention provides a method of injecting a molding compound material between a mounted integrated circuit die and a substrate, improving on the relatively lengthy and unreliable current methods. The invention also provides a mounting method that does not apply wax or flux in the mounting process, and so does not require application of solvents or other cleaning steps in the process. The invention further includes solder bump and contact metals that are oxidation resistant and lead free, reducing the need for flux and decreasing the risk of electromigration in fine-pitch flip-chip applications.

Current flip-chip processes incorporate several steps, and require multiple pieces of equipment to perform these steps. One particular process that is representative of current technology is described here, to contrast with the improvements offered by the invention. First, a flux is applied to the substrate to assist in flowing the lead-based solder bumps between the substrate and the integrated circuit die. Next, the bumped die is inverted and positioned in the proper place on the substrate. The placed integrated circuit die and substrate are then heated in a furnace to flow the solder, and removed from the furnace to cool once the integrated circuit die is attached. The assembly is then defluxed by bathing the assembly with a solvent, to ensure proper adhesion of underfill material. Finally, a liquid underflow material is applied immediately adjacent to multiple sides of the mounted integrated circuit die, so that the liquid underflow material flows into the gap between the mounted integrated circuit die and the substrate by capillary action.

It is necessary to flow the liquid underflow until the void between the integrated circuit die and the substrate is completely filled, which is undesirably time consuming. Liquid underfill is applied from multiple sides of the integrated circuit die to encourage more rapid underfilling, but this method also becomes less effective as integrated circuit dice become larger and the gap between the dice and the substrate becomes smaller. The present invention requires only a few seconds to underfill a typical mounted die, in contrast with a minute or more usually required with liquid underfill processes. For example, a 400 millimeter square chip with a 100 micrometer gap and 225 micrometer bump pitch requires approximately 45 seconds to underfill using the standard liquid capillary underfill process, but only takes three seconds to underfill with the inventive process described herein. The entire process required for typical capillary underfill processes includes joint fluxing, die placement, reflowing solder bumps, defluxing underfilling from multiple locations and curing, and takes from 15 to 30 minutes with typical materials.

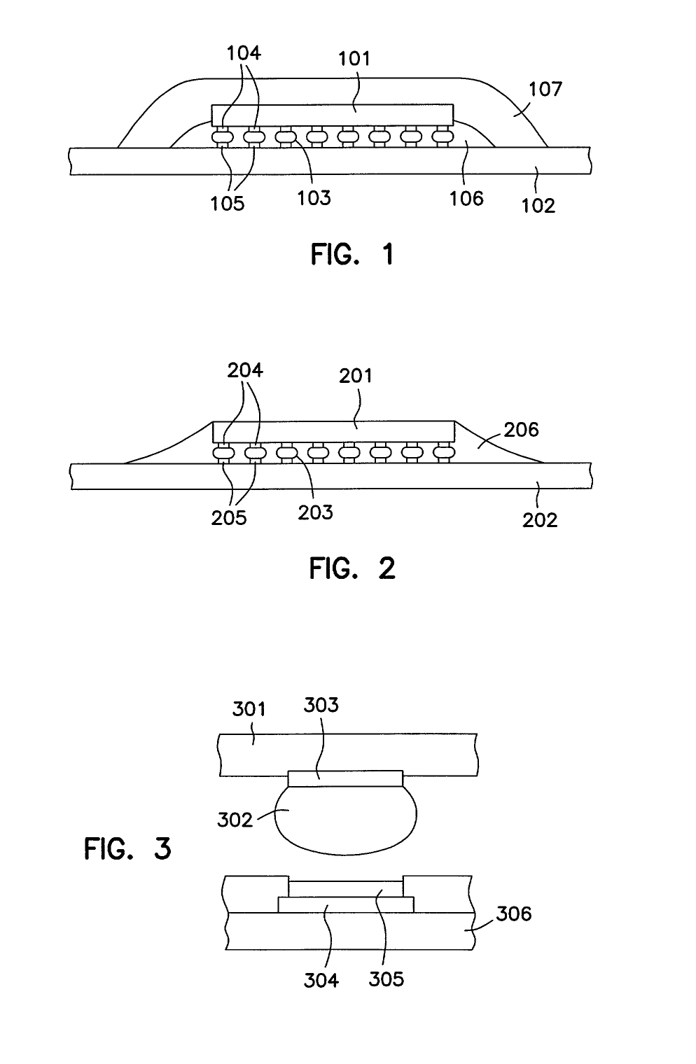

FIG. 1 illustrates a conventional flip-chip mounted to a substrate. The die 101 is mounted to a substrate 102 by reflow of solder bumps 103. The reflowed solder bumps connect die contacts 104 to substrate contacts 105, and so provide an electrical connection between the circuitry on the die and the substrate circuitry. An underfill material is flowed under the die by capillary action and cured. After curing of the underfill material, a molding compound 107 is applied to the die and surrounding substrate to physically secure the die to the substrate.

The physical connection provided by the solder bumps 103 between the die contacts 104 and the substrate contacts 105 is typically not physically strong enough to remain reliable over time as the contacts undergo stress from heating, flexing or vibration of the assembly, and so must be further strengthened with underfill material. The underfill material is applied only after flux has been applied to the substrate, the die has been properly placed on the substrate and the attached solder bumps have been reflowed, and the joined die and substrate are defluxed with a cleaning agent. The underfill 106 is typically a material such as low-viscosity epoxy or other high adhesion material that provides appropriate resistance to stress failure. The underfill is applied near the gap between the die and the substrate, such that capillary action draws the underfill between the die and substrate. Often, underfill applied by capillary action must be applied to more than one location to ensure complete and efficient underfilling of large dice.

But, as bump pitch and bump size decrease with the demand for smaller electronic devices and smaller pitch semiconductor processes employed in die production, the size of the dice continues to increase to support greater numbers of components on a single die. Therefore, it is believed that die size will continue to grow and the gap between the die and substrate will continue to shrink, making capillary underfilling even more time-consuming and increasingly unreliable.

Therefore, a novel method of underfilling a die is needed and here disclosed, which both removes dependence on capillary action and provides a faster and more efficient process that requires less equipment, time and material to practice.

One embodiment of a die mounted to a substrate using such a process is pictured in FIG. 2. Here, the die 201 is mounted to the substrate 202 with a heated placement head, and solder bumps 203 are reflowed between die contacts 204 and substrate contacts 205. The flux and deflux steps are eliminated by use of a nonoxidizing metal surface on the contacts to which the solder bumps are not attached before reflow. Finally, a molded underfill is shown at 206, which in one application step takes the place of both the underfill and the molding compound of the traditional flip chip assembly of FIG. 1.

In the example embodiment of FIG. 3, the die 301 is provided with solder bumps 302 attached to the die contacts 303, such that the solder bumps 302 are to be reflowed after placement on the substrate 306. The substrate contacts 304 are finished with a substrate contact surface 305 that comprises a nonoxidizing metal to facilitate fluxless reflow.

The substrate contacts 304 of a further embodiment comprise a core metal such as nickel or copper, and have a substrate contact surface 305 that comprises a metal that does not oxidize, such as gold or palladium. The solder may be any soft metal that flows at suitably low temperature, and in some embodiments is a lead-free silver-bearing solder. Because solder can flow and readily adhere to a nonoxidizing metal finish such as gold or palladium, no flux or subsequent defluxing is needed.

FIG. 4 illustrates the application of the molded underfill 206, which happens after the fluxless solder reflow. A molding compound tablet is placed on a piston within the lower molding die 402, and the die and substrate assembly 404 is placed in an opening in the lower molding die. An upper molding die 403 is placed in contact with the lower molding die 402, and has within it a shaped die and substrate assembly mold opening 405, a molding compound tablet opening 406, and a molding compound channel 407 connecting the openings 405 and 406.

In operation, the upper molding die 403 and lower molding die 402 are brought together, and a piston exerts pressure on the molding compound tablet 401. In some embodiments, the molding compound tablet is heated to facilitate flow, and the compound becomes substantially more solid upon cooling. The molding compound is forced through molding compound channel 407, and into the opening formed by die and substrate assembly molding compound opening 405 in the upper molding die 403 and the mounted die 404 and the corresponding opening 408 in the lower molding die 402. The shape of the opening and the position of the die and substrate assembly within the opening cause the molding compound forced into the opening to form a molded underfill as illustrated at 206 in FIG. 2.

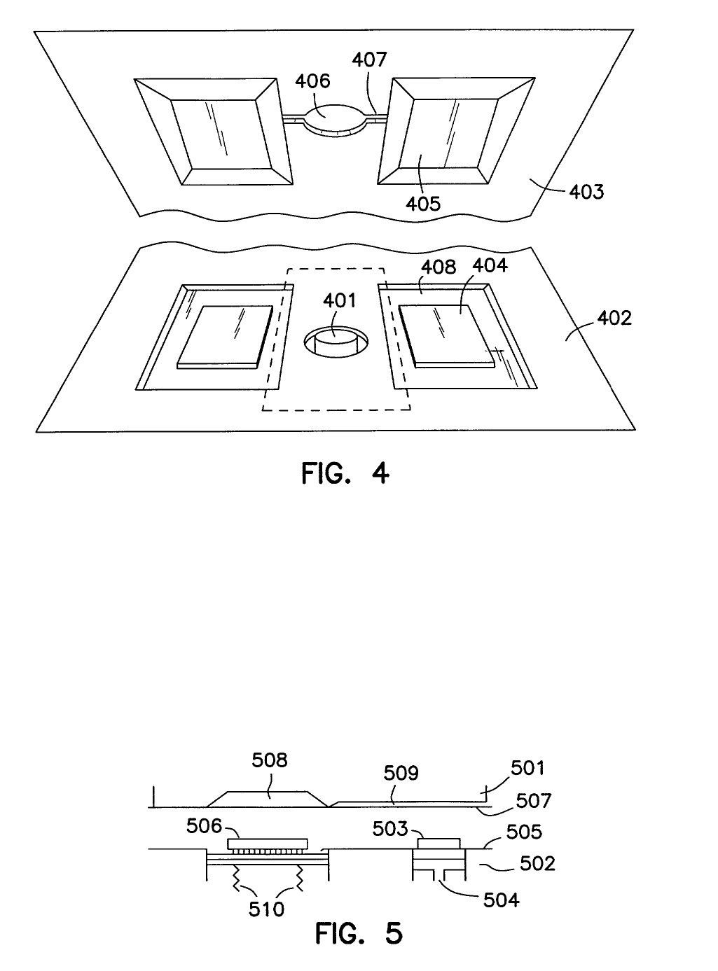

FIG. 5 illustrates a side view of one embodiment of the invention, including an upper molding die 501 and a lower molding die 502 used to create a molded underfill in die and substrate assembly 503. This illustration of the invention shows a molding compound tablet 503 positioned over a piston 504, with release film 505 separating the molding compound from the lower molding die and the piston. A die and substrate assembly 506 rests positioned in an opening in the lower molding die, at which point the release film also has an opening as shown in FIG. 5. Upper die 501 is also covered with release film 507, including the die and substrate molding compound opening 508 which corresponds to 405 in FIG. 4, and molding compound channel 509 which corresponds to 407 in FIG. 4.

To apply the molding compound to the die and substrate assembly, the upper and lower molding dies are brought together and the piston 504 forces the molding compound 503 into the molding compound channel 509 between the release film 505 and 507. The molding compound is forced into the die and substrate molding compound opening 508 formed by the upper and lower dies, and is forced into the gap between the die and the substrate of the die and substrate assembly. The molding compound in some embodiments forms a shaped fillet as shown in FIG. 2 around the edges of the die, as determined by the geometry of molding compound opening 508.

In further embodiments, the die and substrate assembly is forced into position against the release film 507 covering the upper die 501 by a platform biased by springs 510, such that the top of the die is in physical contact with the release film. This embodiment produces a die and substrate assembly with no molding compound on the top surface of the die that is protected from contact with the molding compound, allowing efficient application of a thermal heat sink or other device as desired. Still other embodiments entirely encapsulate the die in molding compound, sealing and protecting the die.

The present invention provides an improved method of mounting a die to a substrate. It provides a novel method of electrically connecting the die to the substrate, and of underfilling the space between the die and the substrate. The invention substantially reduces the time and the number of steps needed to mount a die to a substrate, provides a method of doing so that incorporates relatively simple and inexpensive materials and equipment. The invention eliminates the need for fluxes and defluxing, thereby reducing the chemical byproducts produced in the die mounting process. The invention further provides a very reliable method for mounting a die, incorporating higher percentages of strength-enhancing fillers into the underfill than other technologies allow. The invention is especially beneficial for mounting dice with relatively small bump pitches, as the forced underfill process is better able to fill the void between a die and substrate than a liquid underfill applied via capillary action.

Although specific embodiments have been illustrated and described herein, it will be appreciated by those of ordinary skill in the art that any arrangement which is calculated to achieve the same purpose may be substituted for the specific embodiments shown. This application is intended to cover any adaptations or variations of the invention. It is intended that this invention be limited only by the claims, and the full scope of equivalents thereof.

We claim:

1. A method of attaching an integrated circuit die to a substrate, comprising:
applying solder bumps to contact areas;
placing the inverted integrated circuit die in a desired location such that the solder bumps are in contact with contact areas of the integrated circuit die and the substrate;
heating the solder bumps to mount the die such that the bumps form a connection between the substrate and the integrated circuit; and
underfilling a gap between the mounted integrated circuit die and the substrate by injecting a molding compound into a molding die positioned over the mounted integrated circuit die.

2. The method of claim 1, wherein the solder bumps comprise a metal alloy that resists oxidation.

3. The method of claim 2, wherein the metal alloy that resists oxidation comprises at least one metal selected from the group consisting of gold and tin.

4. The method of claim 1, wherein the contact areas of the integrated circuit die have a contact surface that is comprised of a metal alloy that resists oxidation.

5. The method of claim 1, wherein the contact areas of the substrate have a contact surface that is comprised of a metal alloy that resists oxidation.

6. The method of claim 1, further comprising heating the molding compound before the molding compound is injected into the molding die.

7. The method of claim 1, wherein the molding compound contains substantially no wax.

8. The method of claim 1, further comprising placing a release film between the molding die and the injected molding compound.

9. The method of claim 1, wherein the molding compound comprises 70 percent to 90 percent silica.

10. The method of claim 1, wherein the molding compound comprises 75 percent to 85 percent silica.

11. The method of claim 1, wherein the molding die is shaped and positioned over the mounted integrated circuit die such that the injected molding compound further forms a fillet adjacent to the mounted integrated circuit die.

12. The method of claim 1, wherein the molding die is shaped and positioned over the mounted integrated circuit such that the injected molding compound does not substantially cover a back side of the mounted integrated circuit die.

13. A method of underfilling a gap between a mounted integrated circuit die and a substrate, comprising injecting a molding compound into a molding die positioned over the mounted integrated circuit die.

14. A mounted die assembly, comprising:
an integrated circuit die mounted to a substrate; and
a molding compound material injected between the die and the substrate.

15. The mounted die assembly of claim 14, wherein the mounted integrated circuit die is a flip-chip.

16. The mounted die assembly of claim 14, wherein the molding compound material further forms a fillet adjacent to the mounted integrated circuit die.

17. The mounted die assembly of claim 16, wherein the molding compound does not substantially cover a back side of the mounted integrated circuit die.

18. The mounted die assembly of claim 14, wherein the molding compound contains substantially no wax.

19. The mounted die assembly of claim 14, wherein the molding compound comprises 70 percent to 90 percent silica content.

20. The mounted die assembly of claim 14, wherein the molding compound comprises 75 to 85 percent silica content.

21. The mounted die assembly of claim 14, further comprising solder bumps connecting the die and substrate that are comprised of a metal alloy that resists oxidation.

22. The mounted die assembly of claim 21, wherein the alloy that resists oxidation comprises at least one metal selected from the group consisting of gold and tin.

23. The mounted die assembly of claim 14, further comprising at least one contact area on the integrated circuit die that is comprised of a metal alloy that resists oxidation.

24. The mounted die assembly of claim 14, further comprising at least one contact area on the substrate that is comprised of a metal alloy that resists oxidation.

25. A method of attaching an integrated circuit die to a substrate, comprising:
applying solder bumps to contact areas of the integrated circuit die;
placing the inverted integrated circuit die in a desired location such that the solder bumps are in contact with contact areas of the substrate;
heating the solder bumps to mount the die such that the bumps form an electrical and physical connection between the substrate and the integrated circuit;
applying a release film to a molding surface of a molding die;
positioning the molding die over the mounted integrated circuit die; and
injecting a molding compound between the release film and the mounted integrated circuit die such that the molding compound forms an underfill between the mounted integrated circuit die and the substrate and further forms a fillet adjacent to the mounted die.
